(19) United States
(12) Patent Application Publication
(10) Pub. No.: US 2009/0161470 A1
(43) Pub. Date: Jun. 25, 2009

(54) CIRCUIT FOR DYNAMIC READOUT OF FUSED DATA IN IMAGE SENSORS

(75) Inventor: Arthur Kimmels, Skui (NO)

Correspondence Address: RatnerPrestia, P.O. BOX 980, VALLEY FORGE, PA, 19482, US

(73) Assignee: MICRON TECHNOLOGY, INC., Boise, ID (US)

(21) Appl. No.: 11/960,966

(22) Filed: Dec. 20, 2007

(51) Int. Cl. G11C 17/18; G11C 8/00; H04S 1/00

(52) U.S. Cl. 365/225.7; 365/233.1; 29/592.1

(57) ABSTRACT

A circuit for reading fused data, an image sensing apparatus, a method of reading fused data and a method of manufacturing a circuit for reading fused data. The circuit includes a fuse and a capacitive component configured to provide a data input signal to a data input node of a one bit data storage unit and a signal delay component configured to provide a delayed signal to a clock input terminal of the one bit data storage unit. The method of operating the circuit includes applying a signal to the fuse and to the signal delay element, delaying the signal in the delay element, providing a delayed signal from the delay element to a clock input of a one bit storage element, and providing the signal from the fuse and the capacitive component to a data input of the one bit storage element.

### BACKGROUND OF THE INVENTION

In general, the present invention relates to dynamic readout of fused data in image sensors.

Image sensors, including complimentary metal oxide semiconductor (CMOS) image sensors and charge-coupled devices (CCD), may be used in digital imaging applications to capture scenes. An image sensor may include an array of pixels. Each pixel in the array may include at least a photosensitive element for outputting a signal having a magnitude proportional to the intensity of incident light on the photosensitive element. When exposed to incident light to capture a scene, each pixel in the array outputs a signal having a magnitude corresponding to an intensity of light at one point in the scene. The signals output from each photosensitive element may be processed to form an image representing the captured scene.

During manufacture, each pixel may be tested individually. Tests may detect defective pixel circuits, above or below pixel signal level, or other attributes. Test results, such as addresses of defective pixels, may be written to a ROM provided on the CMOS chip. The ROM may also provide information on the chip, such as lot number, wafer number, position on the wafer, etc.

In one on-chip ROM design, the ROM includes an array of memory cells. Each memory cell includes a fusible conductor. The fusible conductors are arranged in an array of rows and columns, with each being connected between a row line and a column line. To write data to the ROM, fusible conductors in the array may be blown, for example, using a laser. This may be done, for example, to record addresses of defective pixels.

To read the ROM data, a relatively high current may be applied to the fuse. The voltage may then be read at the other end of the fuse. If the fuse is blown, the resistance through the fuse is high, resulting in a relatively large voltage drop across the fuse and a relatively low voltage being read at the other end. On the other hand, if the fuse is not blown, the resistance through the fuse is low, resulting in a relatively high voltage being read at the other end.

### BRIEF DESCRIPTION OF THE DRAWINGS

Included in the drawings are the following figures:

FIG. 1 is a block diagram of an image sensor according to an embodiment of the present invention.

FIG. 2A is a circuit diagram of a circuit for reading fused data according to an embodiment of the present invention.

FIG. 2B is a circuit diagram of a flip-flop suitable for use in the circuit shown in FIG. 2A.

FIG. 3 is a graph of an example set of characteristics for components of the circuit for reading fused data according to the embodiment shown in FIG. 2A.

FIG. 4 is a circuit diagram for reading fused data from a plurality of memory cells according to an embodiment of the present invention.

### DETAILED DESCRIPTION OF THE INVENTION

The ROM cell read out procedure described above has at least the following drawbacks. First, it requires a relatively large semiconductor area per bit cell. Second, it requires application of a relatively large current to the fuse when reading out the fuse. This may lead to current spikes on the supply when a large number of fuses are read out simultaneously, which may introduce noise in sensitive analog circuits. Further, the application of a relatively large current to the fuse requires that power rails to the fuses be made relatively wide, taking up additional semiconductor area.

The embodiments of the present invention, described below, may overcome these problems using a dynamic circuit for reading out the fused data.

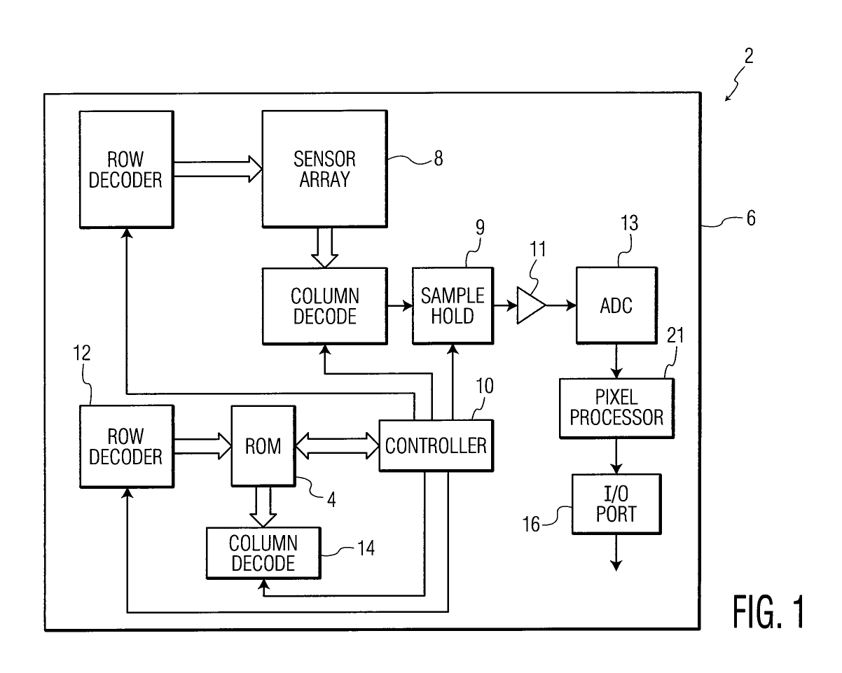

A block diagram of an example image sensing apparatus 2 with an on-chip ROM 4 is shown in FIG. 1. As shown, example image sensing apparatus 2 includes a pixel sensor array 8, a controller 10, an input/output (I/O) terminal and associated interface 16 and an on-chip ROM 4. Controller 10 may operate the row and column decoders 12 and 14 and other signals to enable the analog pixels to be read out of charge accumulation signals row-by-row and column-by-column to sample and hold circuit 9. The signal provided by sample and hold circuit 9 may be amplified by amplifier 11 and converted to digital signals by analog-to-digital converter 13. A pixel processor 21 may digitally process the pixel information and supply the processed information to I/O terminal 16. Controller 10 may also select the memory cells of ROM 4 for read out using row and address decoders 12 and 14.

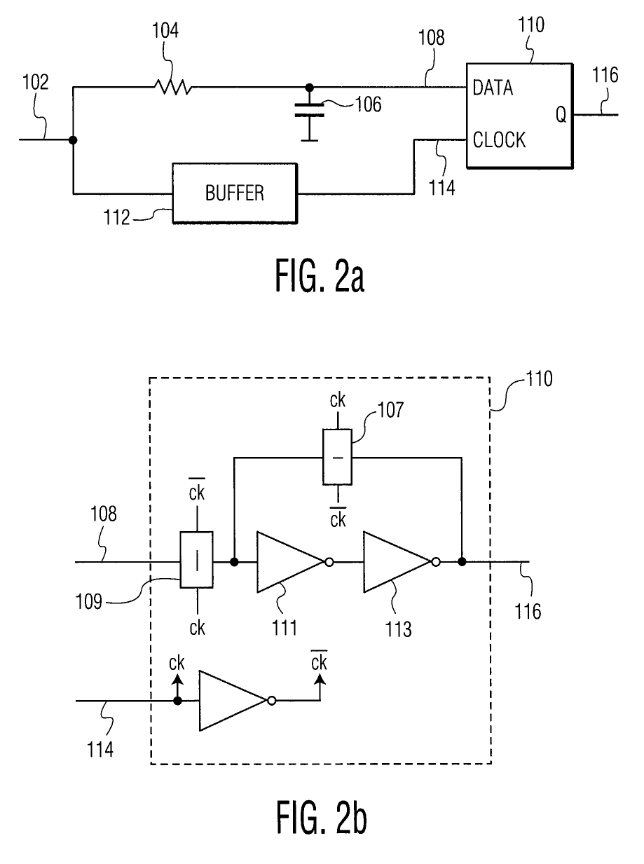

ROM 4 may include an array of breakable fuses arranged in rows and columns. Alternatively, a set of registers may be provided for each pixel for storing an address, for example, of a defective pixel. Each breakable fuse may represent a memory cell of ROM 4. A representative fuse 104, along with its associated readout circuitry, is shown in FIG. 2A. Fuse 104 may be a conductor formed of, for example, polysilicon, and may include a narrowed portion which is subject to breakage when a high voltage or a laser beam is applied to it. It may, however, be any conductor that is configurable to break and be read as described below. In one embodiment of the present invention, fuses in the array are selectively blown using a laser to store data.

As shown in FIG. 2A, the example dynamic fused data readout circuitry 100 shown in FIG. 2A includes circuit input node 102, fuse 104, capacitor 106, flip-flop 110, flip-flop data input terminal 108, flip-flop clock input terminal 114, flip-flop output terminal 116 and buffer 112. The buffer 112 may be, for example, a CMOS buffer circuit formed from two series connected CMOS inverters. Although the invention is described as using a capacitor, it is contemplated that it may be practiced using other reactive impedance components.

Flip-flop 110 may be, for example, a leading edge D-type flip-flop. Generally speaking, using the example leading edge D flip-flop, the data output Q of the flip-flop is high on the leading edge of the clock signal when the data input signal is high, and remains high when the clock signal is released, irrespective of the data signal. An exemplary flip-flop circuit is shown in FIG. 2B. In this circuit, the clock signal, ck, is inverted by an inverter 105 to provide an inverted clock signal, c̅k̅. Data line 108 is coupled to the data input of normally open (non-conductive) transmission gate 109 while the clock signals ck and c̅k̅ are coupled to the control lines. The output terminal of transmission gate 109 is connected to a CMOS latch circuit formed by feedback-coupled inverters 111 and 113. A normally closed (conductive) transmission gate 107 is coupled between the inverters 113 and 111 in the feedback loop. In this configuration, when the clock signal, ck, is logic-high, the transmission gate 109 applies the signal 108 to the input terminal of buffer 111 and the transmission gate 107 provides a high-impedance to the input terminal of buffer 111. When the signal ck is logic-low, however, the transmission gate 109 provides the high impedance while the transmission gate 107 applies the output signal of inverter 113 to the input terminal of inverter 111. It is contemplated that, if the buffer 112 is formed from series connected CMOS inverters, the inverted clock signal c̅k̅ may be the output signal of the first buffer while the clock signal ck may be the output signal of the second buffer. In this configuration, the inverter 105 would not be needed.

In operation, to read a selected fuse, a load signal (Vload) is applied to circuit input node 102, to apply a voltage signal Vload to fuse 104 and buffer 112. The load signal is processed by the RC low pass filter formed by fuse 104 and capacitor 106 and then applied to data input terminal 108 of flip-flop 110. The data signal applied to data input terminal 108 is the low pass filtered version of Vload. If Vload is, for example, a square wave, the data signal may be represented by Vload(1-e^{-t/RC}). The signal Vload undergoes some amount of delay in buffer 112, and the delayed load signal is applied as the clock signal to flip-flop 110.

Generally speaking, if the fuse is blown (or nearly blown), the resistance through the fuse will be high. This results in the RC time constant of the filter being relatively large, causing the filter to have a relatively low cut-off frequency. This filter attenuates the high frequency components of the square wave signal Vload so that the signal applied to the data input terminal of the flip-flop is relatively low when the leading edge of the clock signal is applied to the clock input terminal of flip-flop 110. Because the data input signal is low at the leading edge of the clock signal, the data output Q will not be high. Alternatively, if the fuse is not blown, the resistance through the fuse will be low. This results in the RC time constant of the filter being low. The high frequency components of the square wave signal will be less attenuated and the data input signal will be high at the leading edge of the clock signal and the data output Q will also be high.

The actual results depend, however, on the selected delay (dT) provided by buffer 112, the threshold voltage of flip-flop 116, the resistance actually provided by the blown or un-blown fuse 104 and the capacitance of capacitor 106.

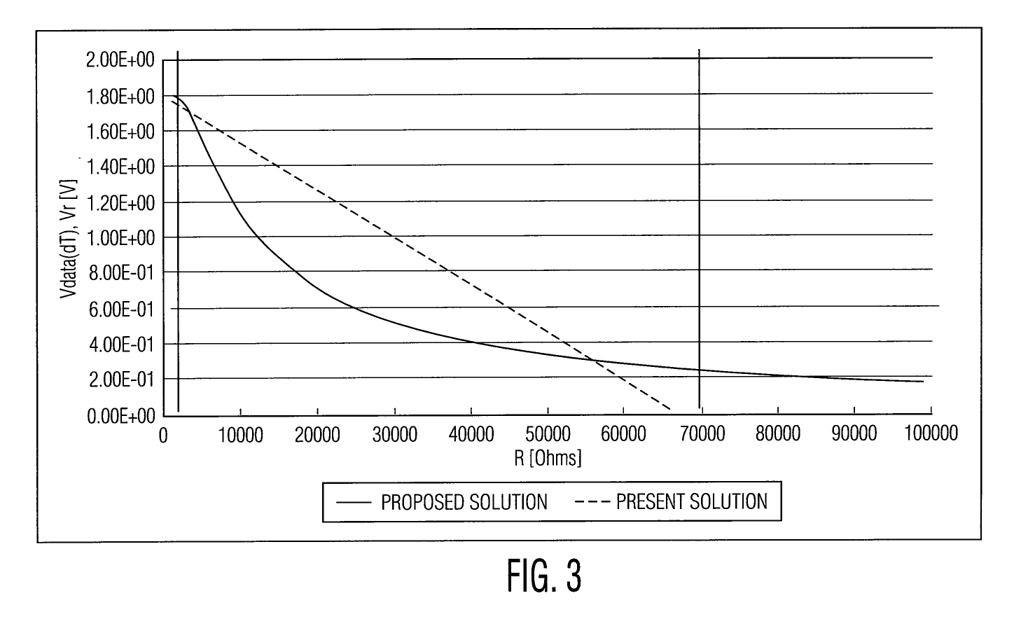

By way of example, FIG. 3 is a graph of different voltage values for the data signal at delayed time dT for different fuse resistance values. This graph assumes dT is 1.0 ns and the capacitance of capacitor 106 is 0.1 pF. At an example maximum value for an un-blown fuse (shown by the solid vertical line on the left-hand side of the graph), the data signal has a voltage of 1.8V. At the minimum value for a blown fuse (shown by the solid vertical line on the right-hand side of the graph), the data signal has a voltage of approximately 0.2V. Using this graph, a flip-flop with an appropriate threshold voltage may be chosen. For example, using the maximum and minimum resistances shown on the graph, a flip-flop that loads a logic value applied to its data input terminal when the logic value is 1.8V at the leading edge of the clock signal would probably be sufficient. However, a flip-flop that loads a logic value applied to its input terminal when the logic value is as low as 0.2 volts may also be sufficient. It is more likely that a voltage somewhere between 0.2V and 1.8V will be selected to allow sufficient room to compensate for errors and other factors.

The range of resistances for fuse 104 may be determined by the specific design used. The delay time (dT) and capacitance may then be selected accordingly. It may, however, be desirable to set dT smaller than 1.0 ns for an area efficient circuit.

The graph shown in FIG. 3 is, of course, only one example. Other graphs may be generated using different delay times (dT) and capacitances. For example, dT may be tuned to provide a wide range of delay times by choosing different transistor dimensions in the buffer. Ideally, however, dT will be set as low as possible to provide maximum area efficiency for the circuit. Further, the graph may be adjusted to account for other factors such as, for example, parasitic capacitance present in the circuit.

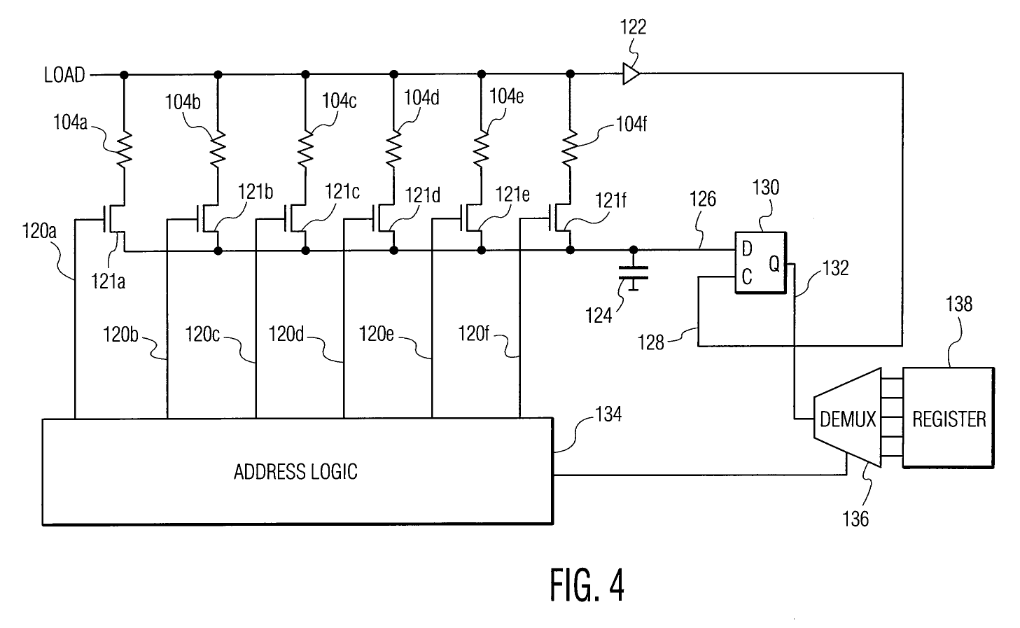

While the readout circuitry shown in FIG. 2A above shows individual readout circuitry (including a capacitive or inductive element, buffer and flip-flop) for each fuse in an array, it may also be possible to provide one readout circuit for a number of fuses in an array. An example readout circuit for multiple fuses is shown in FIG. 4. FIG. 4 shows an example row of fuses, including representative fuses 104a, 104b, 104c, 104d, 104e and 104f. Each fuse is connected to a respective fuse readout transistor 121a, 121b, 121c, 121d, 121e, 121f. Gates of each fuse readout transistor are connected to a respective line 120a, 120b, 120c, 120d, 120e and 120f. Each transistor is also connected to the readout circuitry. The readout circuitry may include capacitive element 124, buffer 122, data input terminal 126, clock input terminal 128, flip-flop 130 and data readout terminal 132, as shown. When address logic 134 applies a read signal to one of the gates, a load signal applied to the corresponding fuse is transferred to the readout circuitry. The load signal is also applied to buffer 122. Readout of the fuse occurs the same as when each fuse has its own readout circuitry. The example shown in FIG. 4 further includes a demultiplexer 136 and register 138 for storing readout values corresponding to the selected addresses.

While the readout circuit shown in FIG. 4 is connected to read out fuses in a single row, the readout circuit may be connected to read out fuses in a single column or in a combination of rows and columns and is not limited to readout of six fuses per readout circuit, as shown.

Data stored in ROM 4 may be accessed by row and column decoders 12 and 14 to read the selected fuse or fuses to determine the stored data. This may occur under control of controller 10, which supplies row and column addresses for read out functions to row and column decoders 12 and 14 and supplies a read voltage to the source terminals of the appropriate row select transistors. The program and readout circuit, for example ROM 4, may also be implemented independently of controller 10.

The embodiments above are described in terms of using a buffer 112 and a flip-flop 110. Element 112 may, however, be any element capable of providing time delay for a signal. Similarly, element 110 may be any suitable digital storage element or any suitable digital logic element, such as, for example, a transmission gate or an AND gate (not shown).

Further, the embodiments described above are described in terms of using a capacitor 106. Element 106 may, however, be any type of capacitor or capacitance. For example, a diffusion capacitance may be used. A diffusion capacitance, for example, may prevent the data input of the flip-flop from remaining floating when the resistance of the blown fuses become extremely high. By way of other examples, element 106 may be the parasitic capacitance associated with the fuse terminals, gate capacitance, poly/poly capacitance, metal/metal capacitance, and so on.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A circuit for reading data, comprising:
a reactive circuit configured to receive a pulse signal and to produce an output pulse having a shape determined by the reactive circuit; and
a delay element configured to receive the pulse signal and to produce a delayed pulse indicating a time at which the output pulse of the reactive circuit is to be sampled.

2. The circuit of claim 1, wherein:
the reactive circuit includes a fuse and a reactive impedance component, and
the shape of the output pulse depends at least on a status of the fuse.

3. The circuit of claim 2,
wherein the delay element is configured to delay the pulse independently of the status of the fuse.

4. The circuit of claim 1, further comprising:
a digital storage unit configured to sample the output pulse of the reactive circuit at the time determined by the delayed pulse.

5. The circuit of claim 1, further comprising:
a digital logic unit configured to sample the output pulse of the reactive circuit at the time determined by the delayed pulse.

6. The circuit of claim 5, wherein:
the digital logic unit is a transmission gate, and
the transmission gate has a data input terminal coupled to the reactive circuit and a control input terminal coupled to the delay element, the transmission gate providing an output signal having a level of the output pulse of the reactive circuit and a level of the delayed pulse at the time determined by the delayed pulse.

7. A circuit for reading stored data comprising:
an RC circuit portion including a fuse and a capacitive component;
a signal delay component; and
a one bit storage unit having at least a data input terminal, a clock input terminal and a data output terminal,
wherein the RC portion of the circuit is connected to the data input terminal and the signal delay element is connected to the clock input terminal.

8. The circuit of claim 7, wherein the delay component includes a CMOS buffer circuit.

9. The circuit of claim 8, wherein the CMOS buffer circuit includes at least two series connected CMOS inverters which provide respective inverted and non-inverted clock signals to the one-bit storage unit.

10. The circuit of claim 7, wherein the capacitive component is selected from the group consisting of a capacitor, a parasitic capacitance associated with terminals of the fuse, a diffusion capacitance, a gate capacitance, a poly/poly capacitance and a metal/metal capacitance.

11. The circuit of claim 7,
wherein the signal delay component is a buffer configured to delay a signal provided to the buffer by a predetermined amount,
and wherein the amount of delay and the capacitance of the capacitive component is determined according to a predetermined range of resistances of the blown or un-blown fuse.

12. The circuit of claim 11, wherein the amount of delay is between 0.1 ns and 1.5 ns.

13. An image sensing apparatus comprising:
an array of photodiodes and an array of fuses,
wherein the array of fuses has at least one readout circuit, the readout circuit comprising:
an RC circuit portion including at least one fuse in the array and a capacitive component;
a signal delay component coupled to the at least one fuse; and
a one bit storage unit having at least a data input terminal, a clock input terminal and a data output terminal,
wherein the capacitive component and the at least one fuse are coupled the data input terminal and the signal delay element is connected to the clock input terminal.

14. The image sensing apparatus of claim 13, wherein each fuse in the array of fuses has a respective associated readout circuit.

15. The image sensing apparatus of claim 14, wherein the array of fuses is an on-chip read only memory (ROM), each fuse comprising a memory cell of the on-chip ROM,
and wherein each respective fuse is either blown or un-blown, the blown or un-blown fuse providing a data value stored in the respective memory cell.

16. The image sensing apparatus of claim 15,
wherein a resistance of the fuse is relatively high when the fuse is blown and the resistance of the fuse is relatively low when the fuse is un-blown,
and wherein the one bit storage unit is configured to provide a one bit data signal that has a value of either high or low depending at least on the resistance of the fuse and a capacitance of the capacitive element, the value of the one bit data signal indicating the data value stored in the respective memory cell.

17. The image sensing apparatus of claim 16,
wherein the RC portion of the circuit is configured to provide a data input signal to the data input terminal of the one bit storage unit coincident with the delayed signal provided by the signal delay component, a voltage of the data input signal depending at least on the resistance of the fuse and the capacitance of the capacitive element,
and wherein the one bit storage unit is a leading edge D-type flip-flop configured to load a logic high value when the voltage of the data input signal is greater than or equal to a predetermined threshold value on the leading edge of the clock signal and to load a logic-low value when the voltage of the data input signal is less than the predetermined threshold value on the leading edge of the clock signal.

18. The image sensing apparatus of claim 14, further comprising:
address logic configured to select a respective fuse or a plurality of fuses in the array to be read by the respective readout circuitry; and
a controller configured to supply an address of the fuse or fuses to be read out by the address logic.

19. The image sensing apparatus of claim 14,
wherein the signal delay component is a buffer configured to delay a signal provided to the buffer by a predetermined amount,
and wherein the predetermined amount of delay and the capacitance of the capacitive component are configured to detect a range of blown fuse resistances.

20. A method of reading data, the method comprising the steps of:
applying a signal to a fuse and to a signal delay element;
delaying the signal by a predetermined amount of time in the delay element and providing a delayed signal from the delay element to a clock input of a one bit storage element; and
providing the signal from the fuse to a capacitive component and to a data input of the one bit storage element.

21. The method of claim 20, further comprising the step of:
providing an output signal from a data output terminal of the one bit storage element, a value of the output signal depending at least on whether the fuse is blown or un-blown and a capacitance of the capacitive element.

22. A method of manufacturing an image sensing apparatus, the method comprising the steps of:
forming a fuse element coupled to a circuit input node;
forming a capacitive component coupled to the fuse element;
forming a buffer element coupled the circuit input node;
forming a storage element having an input data terminal coupled to the capacitive component and the fuse element, an input clock terminal coupled to the buffer element and an output terminal.

23. The method of manufacturing the image sensing apparatus of claim 22, further comprising the step of:
selecting a delay constant for the buffer and a capacitance for the capacitor depending on a predetermined range of resistances for the fuse in a blown and an un-blown state.

24. The method of manufacturing the image sensing apparatus of claim 23, wherein the delay constant is selected to be between 0.1 ns and 1.5 ns.

25. The method of manufacturing the image sensing apparatus of claim 23, further comprising the step of:
selecting a voltage for the data storage element such that the data storage element will load a logic high value when a signal greater than or equal to the voltage level is applied to its data input terminal at a leading edge of a signal applied to the clock input terminal and will load a logic-low value otherwise.
